(19) United States
(12) Patent Application Publication
(10) Pub. No.: US 2011/0050215 A1
(43) Pub. Date: Mar. 3, 2011

(54) SYSTEM FOR APPLYING MAGNETIC FORCES TO A BIOSENSOR SURFACE BY MECHANICALLY MOVING AT LEAST ONE MAGNET

(75) Inventors: Josephus Arnoldus Henricus Maria Kahlmann, Eindhoven (NL); Albert Hendrik Jan Immink, Eindhoven (NL); Jeroen Hans Jeroen, Eindhoven (NL); Thea Van Der Wijk, Eindhoven (NL); Femke Karina De Theije, Eindhoven (NL)

(73) Assignee: KONINKLIJKE PHILIPS ELECTRONICS N.V., EINDHOVEN (NL)

(21) Appl. No.: 12/517,863

(22) PCT Filed: Dec. 7, 2007
(86) PCT No.: PCT/IB07/54967

§ 371 Date: Nov. 16, 2010

(30) Foreign Application Priority Data
Dec. 12, 2006 (EP) 06125906.5

(51) Int. Cl. G01R 33/02

(52) U.S. Cl. 324/244

(57) ABSTRACT

A magnetic system for biosensors or a biosystem, wherein magnetic particles that interact with molecules are brought into a magnetic field, in order to be influenced via magnetic attraction or repulsion forces. The external magnetic field is varied by mechanically moving the magnetic poles of at least one magnetic relative to the sensor or at least its surface to allow the magnetic force to be switched between effective attraction towards the sensor surface and effective repulsion away from the sensor surface.

### FIELD OF THE INVENTION

The invention relates to a magnetic system for biosensors.

### BACKGROUND OF THE INVENTION

Biosensors based on the detection of magnetic beads have promising properties for biomolecular diagnostics, in terms of speed, sensitivity, specificity, integration, ease of use, and costs.

An important assay step in a biosensor is the so called stringency step, in which a distinction is made between signals due to weak and due to strong biochemical binding. In such a step, the magnetic particles, also referred to as beads in the following, are put under stress to test the strength of the biological binding between the particle and a biologically active sensor surface of the biosensor. This allows discrimination between magnetic particles that are specifically bound and magnetic particles that are non-specifically bound to the sensor surface.

From US 2004/0219695 A1 it is further known to use magnetic or electric fields for attracting molecules labeled with magnetically or electrically active particles to binding sites and/or for removing unbound labeled molecules from a sensor region.

For application in a magnetic biosensor, it has been proposed to use external field generating means (coils) outside the sample volume for a washing step, at which superfluous magnetic particles are removed. Large magnetic fields and related large magnetic field gradients are required to generate a reasonable force on the magnetic particles in the sample volume and special measures have to be taken not to influence the magnetic sensor behavior and to avoid bead clustering, the gathering of magnetic particles.

The electromagnets consist of a core of material with high permeability (e.g. ferrite material) and a number of wires wound around this core. This has some advantages such as:

External (electro)magnets have a relatively large interaction range, which allows collecting beads from a large reaction chamber.

Homogeneous field gradients can be generated in a configuration with external magnets, which is crucial in performing a stringency step.

But also this configuration has some distinct disadvantages:

Only relatively low magnetic fields can be generated (in the order of about 0.1 T for core diameters of 3 mm and about 100 windings with peak currents of about 5 A). The required high peak currents are especially cumbersome in hand-held applications (such as a road-side drugs-of-abuse tester).

### SUMMARY OF THE INVENTION

It is an object of the present invention to achieve a magnetic system for biosensors, which is compact and effective.

The stated object is achieved for a magnetic system for the use in biosensors by the features of patent claim 1.

Further embodiments of this system or device are characterized in the dependent claims 2-15.

The basic idea and function of the invention is, that magnetic beads are influenced via magnetic attraction or repulsion forces, wherein the magnetic poles of at least one magnet can be mechanically moved in a relative way to the sensor or at least the sensor surface.

In the present invention it is proposed to use a special magnetic system, in which the magnetic force can be switched between effective attraction towards the sensor surface and effective repulsion away from the sensor surface.

In a first embodiment a mechanical support, containing at least one magnet, is movable relatively to the sensor or sensor chip. In a preferred embodiment a moveable mechanical support contains two magnetic poles that are arranged on a common axis together with the sensor and the cartridge. By changing the position of the mechanical support, the distance between the sensor to each of the magnetic poles can be varied.

In another embodiment, the sensor is physically coupled to the cartridge and is moveable linearly between two magnetic poles, which are arranged adjacent to each other in a common axis together with the sensor and the cartridge.

A further embodiment discloses that at least one of two permanent magnets can be shifted linearly from a position out of the mentioned common axis into a position in line with the axis and vice versa.

A further alternative embodiment is disclosed in which the movement from besides the axis into line with the axis and vice versa is realized by a pivot movement or rotational movement of the magnet, or the magnets.

A further embodiment discloses a construction by which the rotational movement or pivot movement can be realized effectively. The rotational movement or pivot movement of the magnet is realized by arranging at least one of the magnets on an eccentric position on a disc, of which the axis of rotation is parallel to the axis of the magnets.

In all alternative aforesaid embodiments a magnetic bypass of the high magnetic force will be caused, when the permanent magnet is shifted or pivoted or rotated out of the magnetic axis of the sensor position. This magnetic bypass is realized by one C-ring-formed magnetic circuit per permanent magnet, wherein the permanent magnet is moved into this space between the poles of the C-ring when it is moved out of the magnetic axis, wherein the C-ring is arranged parallel to the aforesaid magnetic axis, in order to bypass the magnetic field, when the permanent magnet is rotated or shifted or pivoted out of the magnetic axis position. In a last embodiment, a magnetic bypass is realized by one C-ring shaped magnetic circuit per pair of magnets with two open spaces in which the permanent magnets are shifted or pivoted or rotated when they are moved out of the magnetic axis of the sensor position.

Detailed embodiment are displayed in the drawings and described in the following.

### DRAWINGS

Different embodiments of the invention are shown in FIG. 1 to FIG. 5. FIG. 6 and FIG. 7 show an assay setup in connection with biosensors or biosystems and results of measurements obtained by the magnetic system, respectively.

FIG. 1 shows a schematic side view of a magnetic system with two magnets arranged at a mechanical support which are moveable in a relative manner to a cartridge with a sensor generating a magnetic field to the cartridge with the sensor, showing two positions of the cartridge with sensor in relation to the magnets,

FIG. 2 shows a magnetic system similar to FIG. 1 with a single C-shaped magnet movable in relation to the cartridge with sensor,

FIG. 3 shows a magnetic system similar to FIG. 1 with two electromagnets passed by two currents changing the relation of current strength between the two currents,

FIG. 4a shows a schematic side view of a magnetic system in a different embodiment with permanent magnets moving from a position A adjacent to the sensor to a position B at a C-shaped magnet in which the permanent magnet and the C-shaped magnet form an essentially closed ring and a closed magnetic circuit,

FIG. 4b shows a schematic side view of a magnetic system according to FIG. 4a in a position B in which the permanent magnet and the C-shaped magnet form an essentially closed ring and a closed magnetic circuit,

FIG. 5 shows a schematic side view of a magnetic system with a permanent magnet arranged at a disc rotating around an axis and a plan view on the rotatable disc,

FIG. 6 shows two schematic drawings of an assay set up with mounted antigens and magnetic particles with attached antibodies binding to the antigens as well as a magnet for removing unbound magnetic particles,

FIG. 7 shows a histogram of luminescence measured before procedure of washing the sensor with the magnet at the left and after washing the sensor at the right.

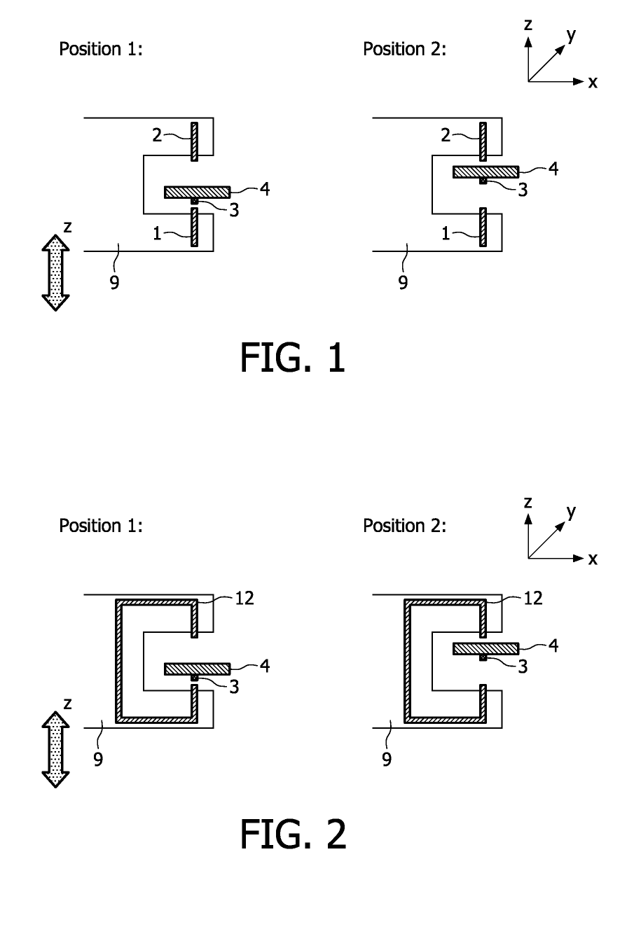

FIG. 1 shows a first embodiment with a first magnet 1 and a second magnet 2, both arranged at a moveable mechanical support 9. A cartridge 4 comprising a sensor 3, shown in FIG. 1 below the cartridge 4, is arranged nearby the mechanical support 9. The sensor 3 is designed to measure the concentration of magnetic particles 15 as an indication of several parameters, as the amount of antibodies in a fluid, for example. The sensor 3 can therefore be referred to as a biosensor. The cartridge 4 contains inter alia a fluid to be analyzed with dissolved magnetic particles 15, also named beads. In order to attract magnetic particles 15 or beads towards or repel beads from the surface of the sensor 3 or sensor chip the two magnets 1, 2 generating a magnetic field are attached to a moveable C-shaped mechanical support 9. The first magnet 1 is arranged below the sensor 3, the second magnet 2 is arranged above the sensor 3, as displayed in FIG. 1. By varying the z-direction of the mechanical support 9, the magnetic field of one of the magnets 1, 2 becomes dominant at the sensor 3. In position 1, shown at the left side of FIG. 1, magnetic particles 15 are attracted towards the sensor surface by the first magnet 1 below the sensor 3. In position 1 the C-shaped mechanical support 9 is in a higher position relating to direction z, defined by the double sided arrow. In position 1 the sensor 3 is near to the first magnet 1 and far to the second magnet 2. In position 2 the U-shaped mechanical support 9 is in a lower position relating to direction z. In position 2 the sensor 3 is near to the second magnet 2 and far from the first magnet 1. In position 2 magnetic particles 15 are pulled away from the sensor surface by the second magnet 2. The process of removing magnetic particles 15 from the sensor surface is also called washing. At least one magnet 1, 2 may be a permanent magnet 13 or an electromagnet. Additionally is mentioned, that in FIGS. 1, 2, 3 the in-plane (x and y) field component may be always minimal, because the sensor 3 is positioned such that it moves along the z-axis where the x and y gradient of the magnetic field is zero.

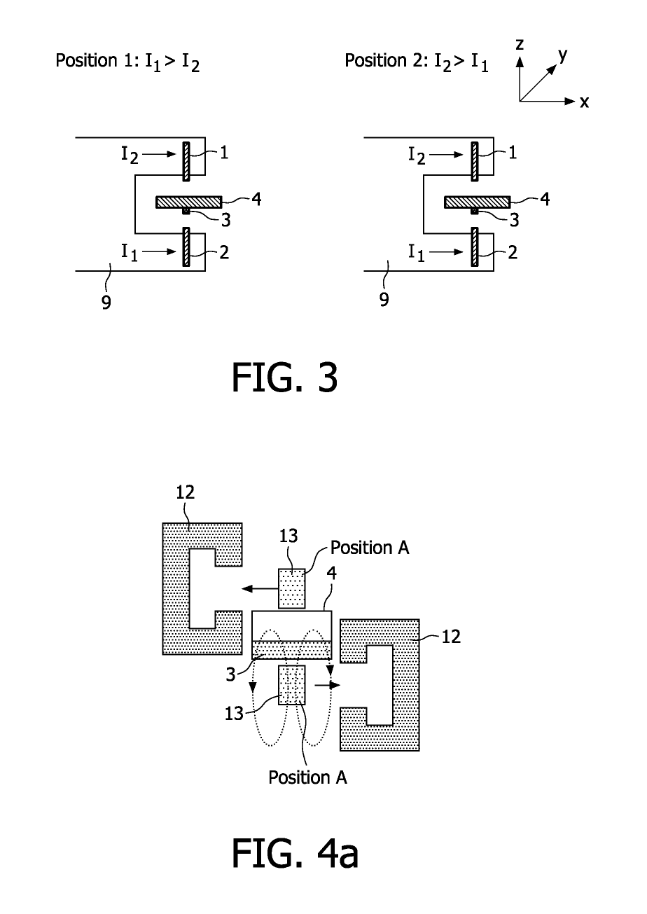

In this embodiment according to FIG. 1 both permanent magnets and electromagnets can be used. Further alternative embodiments are shown in FIGS. 2 and 3.

In the embodiment shown in FIG. 2, a single C-shaped magnet 12 is used instead of two magnets 1, 2 as stated in FIG. 1. The C-shaped magnet 12 is integrated in the mechanical support 9 with end portions protruding out of the mechanical support 9. The complete C-shaped magnet 12 mounted at the mechanical support 9 is moveable relatively to the sensor 3 and the cartridge 4. Relative movement of the cartridge 4 to the C-shaped magnet 12 means that either the cartridge 4 moves in z direction up or down, whereby the C-shaped magnet 12 keeps position, or the C-shaped magnet 12 moves in z direction up or down, whereby the cartridge 4 with sensor 3 keep their position.

In FIG. 3 an embodiment is shown in which changing the current balance between the first magnet 1 and the second magnet 2, which are designed as electromagnets in this embodiment, changes the magnetic field to force (move) magnetic particles 15 towards and from the sensor surface. At least the strength of one current I₁, I₂ through magnets 1, 2 is controllable. In position 1, shown at the left side of FIG. 3, current strength I₁ at the first magnet 1 below is higher than current I₂ at the second magnet 2 above. In position 2, shown at the right side of FIG. 3, current strength I₁ at the first magnet 1 below is smaller than current I₂ at the second magnet 2 above. The magnetic field generated by the first magnet 1 and the second magnet 2 exerts a force in the area essentially between the first magnet 1 and the second magnet 2 in which the cartridge 4 with fluid to be examined and magnetic particles 15 is accommodated. By this means magnetic particles 15 in the cartridge 4 are pulled towards the sensor 3 in the case of position 1, whereby the magnetic particles 15 are pulled away from the sensor 3 in the case of position 2 at the right side of FIG. 3.

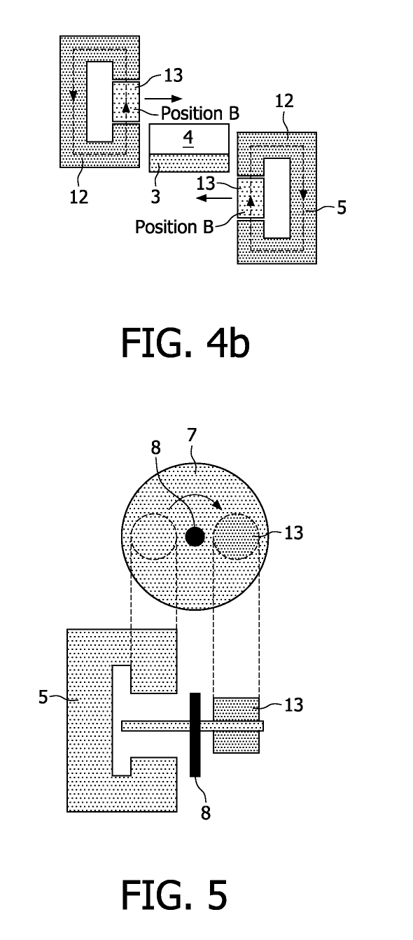

FIG. 4a, FIG. 4b show an advantageous embodiment for the use of strong permanent magnets 13, one permanent magnet 13 related to a C-shaped magnet 12 at the left side and another permanent magnet 13 related to a C-shaped magnet 12 at the right side of FIG. 4a. The C-shaped magnet 12 is similar to the C-shaped magnet 12 of the embodiment of FIG. 2. In FIG. 4a, FIG. 4b the C-shaped magnet 12 is not supported by a mechanical support 9 but forms a support itself. Between the two C-shaped magnets 12 a cartridge 4 with reaction chamber and a sensor 3 for measuring the amount of magnetic particles 15 in the cartridge 4 is arranged. In the position A in FIG. 4a with the permanent magnets 13 near to the sensor 3 the magnetic field from the permanent magnets 13 will cause actuation in the reaction chamber of the cartridge 4 above the sensor 3 or sensor chip. This can be either attraction in the direction to the sensor 3, this means in the direction downwards in FIG. 4a, or pulling from the sensor 3 (washing), this means in the direction upwards in FIG. 4a, depending on the polarization of the permanent magnets 13. For subsequent steps in analyzing the fluid in the cartridge the influence of the permanent magnets 13 has to be removed. In the case of permanent magnets 13 this is done by removing the permanent magnets 13.

In removing the permanent magnets 13, typically two problems need to be solved:

a) one has to move the strong permanent magnet 13 over a large distance to avoid any stray fields from the magnet to influence the sensor 3 when the permanent magnet 13 is in a position far from the sensor 3.
b) mechanical movement is needed in the reader device.

The solution to these problems is to place the permanent magnets 13 in a magnetically closed loop in case the permanent magnet 13 are in a position at a larger distance away from the sensor 3, referred to as position B, shown in FIG. 4b. The permanent magnets 13 are moved from a position near to the cartridge 4 and sensor 3 to a position far form the cartridge 4 and sensor 3, whereby in the later position the permanent magnets 13 each essentially close the space of the C-shaped magnets 12 between the magnetic poles to essentially generate a closed circuit. Practically, all of the magnetic field lines of the permanent magnets 13 will now go through a magnetic circuit 5 provided in this example by the C-shaped magnets 12, which effectively nearby nullifies its influence on the magnetic biosensor or sensor 3. The configuration of the magnetic system should be such that air gaps at the edges between the permanent magnets 13 and the C-shaped magnets 12 are as small as possible and magnetic fringe fields caused by these gaps are minimal. That means, when the permanent magnet 13 is not used or should not be active, the magnetic field lines are brought in magnetic bypass by moving the permanent magnet 13 into the gap of the magnetic circuit closing the space of the C-shaped magnet 12. The C-shaped magnets 12 each generating a magnetic circuit 5 are preferably made of a highly permeable material that shows no remanent magnetisation.

It is therefore proposed to use small strong permanent magnets 13 (e.g. FeNdB; Iron Neodymium Bohr) and to move these permanent magnets 13 in a linear or rotational mechanical movement from a position A near to the sensor 3 to a position B at a larger distance from the sensor 3.

The advantages of using external permanent magnets 13 would be:

Permanent magnets 13 do not cause any power dissipation.

Permanent magnets 13 can generate larger magnetic fields (and field gradients) in the order of 1-2 Tesla.

Furthermore, several mechanical actuation mechanisms are possible. One possible embodiment is shown in FIG. 5 where the permanent magnet 13 is placed in or on a rotatable disc 7. The rotatable disc 7 rotates around a bolt 8 and by this rotation shifts the attached permanent magnet 13 in a position near to the sensor 3, referred to as position A, and in a second position away from the sensor 3 closing the space of the C-shaped magnet 12, referred to as position B. Preferably, the actuation mechanisms are bi-stable in two possible positions A and B (see FIG. 4).

Only a small, weak mechanical actuation should be necessary to move the permanent magnet 13 from position A to position B and vice versa. Such a configuration is for example known in optical storage to move a CD or a DVD lens in the optical path in a double reader or double-write drive. In this technical field such an actuator is sometimes referred to as a ‘pole-actuation’.

Using the setup described above it is possible to accomplish a washing step for removing unwanted magnetic particles 15 without using fluids for washing the magnetic particles 15 away from the sensor 3. For a competitive assay experiments with a well plate proved that a permanent magnet 13 (˜1.2 T at surface) above the binding surface (˜1.5 mm) can discriminate well between specific and non-specific bound magnetic particles 15.

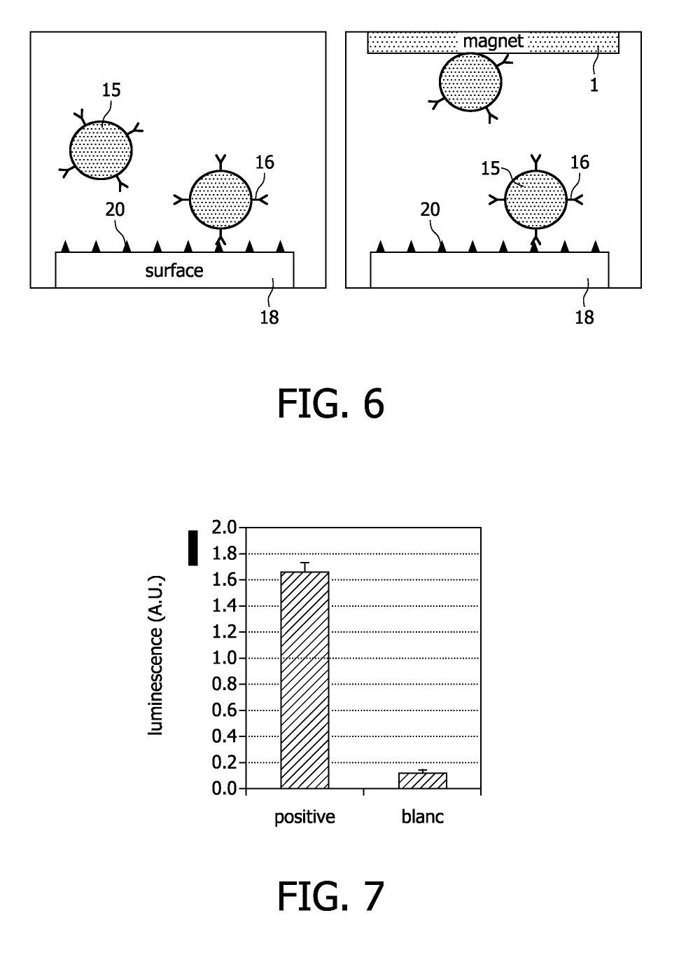

FIG. 6 shows two schematic drawings of an assay set up with mounted antigens 20 and magnetic particles 15 with attached antibodies 16 binding to the antigens 20 as well as a magnet 1 for removing unbound magnetic particles 15. Commonly, the assay set up is administered by a fluid to be examined in which the magnetic particles 15, the antibodies 16, and the antigens 20 are dissolved in a solution. The assay setup is implemented in a well plate, in which a surface 18 is covered with the antigens 20 to which the magnetic particles 15 covered with antibodies 16 can bind once they reach the surface 18. This binding process can be accelerated using a magnet beneath the surface 18 (not shown). At the right side of FIG. 6 a magnet 1 is placed at a certain distance above the surface 18 in order to fish the unbound magnetic particles 15 out of the solution. The magnetic particles 15 that are not bound via antibodies 16 to the antigens 20 at the surface 18 are forced to move to the magnet 1, shown at the right side of FIG. 6. After this washing step unwanted magnetic particles 15 are adequately far away from the surface 18 not to be detected by a subsequent detection step in which the amount of magnetic particles 15 bound to the surface 18 is measured. Regularly, the bound magnetic particles 15 are detected as an indication for the amount of antibodies 16 bound to the magnetic particles 15. The subsequent detection step can be based on magnetic detection, optical detection, acoustic detection or other detection techniques.

FIG. 7 shows a histogram of a measurement of luminescence measured before procedure of washing the sensor 3 with the magnet 1, 2, 12, 13 at the left, referred to as positive, and after washing the sensor 3 at the right, referred to as blanc. The magnetic particles 15 that remain on the surface 18 are labeled with a horseradish peroxidase (HRP)-tagged secondary antibody 16. HRP is an enzyme that catalyses the conversion of luminol, which releases photons, which are optically detected. Luminescence was measured upon incubation with luminol, which is a measure for the amount of magnetic particles 15 on the surface 18, as luminol is bound to the magnetic particles 15 in this example, corresponding to the binding of antibodies 16 to magnetic particles 15 as shown in FIG. 6. As a result of processing the assay set up with means of the magnetic system described above, the optical detection signal is strongly reduced. At the right, blanc, only signals are measured originated from bound magnetic particles 15, unbound magnetic particles 15, which are still present at the left side, positive, are removed and do not contribute any more to the optical signal.

The particular combinations of elements and features in the above detailed embodiments are exemplary only; the interchanging and substitution of these teachings with other teachings in this are also expressly contemplated. As those skilled in the art will recognize, variations, modifications, and other implementations of what is described herein can occur to those of ordinary skill in the art without departing from the spirit and the scope of the invention as claimed. Accordingly, the foregoing description is by way of example only and is not intended as limiting. The scope of the invention is defined in the following claims and the equivalents thereto. Furthermore, reference signs used in the description and claims do not limit the scope of the invention as claimed.

### REFERENCE NUMBERS

1 first magnet
2 second magnet
3 sensor
4 cartridge
5 magnetic circuit
7 rotatable disc
8 bolt
9 mechanical support
12 C-shaped magnet
13 permanent magnet
15 magnetic particles
16 antibody
18 surface
20 antigen

1. A magnetic system for biosensors or a biosystem, wherein magnetic particles (15) are brought into a magnetic field, in order to be influenced via magnetic attraction or repulsion forces, wherein at least one magnet (1, 2, 12, 13) is mechanically moved relatively to the position of the sensor (3) or at least the sensor surface.

2. A magnetic system according to claim 1, characterized in that the sensor (3) is physically coupled directly to a cartridge (4) containing the biomaterial to be analysed.

3. A magnetic system according to claim 1, characterized in that at least two magnets (1, 2) can be moved simultaneously with respect to the sensor (3) and the cartridge (4) by arranging the at least two magnets (1, 2) at a mechanical support (9).

4. A magnetic system according to claim 2, characterized in that the sensor (3) and the cartridge (4) are movable linearly between two magnetic poles of the magnet (1, 2, 12), which are arranged adjacent to each other in a common axis.

5. A magnetic system according to claim 4, characterized in that at least one of the two permanent magnets (13) are shifted linearly from the side out of the common axis into a position in line with the common axis et vice versa.

6. A magnetic system according to claim 4, characterized in that the movement from out of the common axis into the position in line with the common axis et vice versa is realized by a pivot movement or rotational movement of at least one of the permanent magnets (13).

7. A magnetic system according to claim 6, characterized in that the rotational movement or pivot movement of the permanent magnet (13) is realized by arranging the permanent magnet (13) on an eccentric position on a rotatable disc (7) which axis of rotation is parallel to the axis of the magnets (1, 2, 12).

8. A magnetic system according to claim 5, characterized in that one C-formed magnet (12) is arranged per permanent magnet (13), wherein the permanent magnet (13) is moved into the space between the poles of the C-formed magnet (12) in order to bypass the magnetic field creating a closed magnetic circuit (5).

9. A magnetic system according to claim 1, characterized in that the permanent magnets (13) are made of material with high magnetic remanence, like FeNdB.
